(19) United States
(12) Patent Application Publication
(10) Pub. No.: US 2016/0079473 A1
(43) Pub. Date: Mar. 17, 2016

(54) SEMICONDUCTOR LIGHT EMITTING ELEMENT AND MANUFACTURING METHOD THEREOF

(71) Applicant: KABUSHIKI KAISHA TOSHIBA, Tokyo (JP)

(72) Inventors: Rei HASHIMOTO, Edogawa Tokyo (JP); Kei KANEKO, Yokohama Kanagawa (JP); Satoshi MITSUGI, Kawasaki Kanagawa (JP); Chie HONGO, Yokohama Kanagawa (JP)

(21) Appl. No.: 14/635,924

(22) Filed: Mar. 2, 2015

(30) Foreign Application Priority Data
Sep. 12, 2014 (JP) 2014-187112

(51) Int. Cl. H01L 33/22; H01L 33/16; H01L 33/20; H01L 33/00; H01L 33/32

(52) U.S. Cl. CPC H01L 33/22; H01L 33/0075; H01L 33/32; H01L 33/20; H01L 33/16

(57) ABSTRACT

A semiconductor light emitting element includes a first layer, a second layer, an intermediate layer, and a third layer. The first layer has a first surface having roughness including concave portions of which side surfaces are inclined and a second surface on an opposite side to the first surface. The first layer includes a first conductive-type first semiconductor layer. The second layer includes a second conductive-type second semiconductor layer. The intermediate layer is provided between the second surface and the second layer. The third layer is provided in the concave portions.

### CROSS-REFERENCE TO RELATED APPLICATION

This application is based upon and claims the benefit of priority from Japanese Patent Application No. 2014-187112, filed Sep. 12, 2014, the entire contents of which are incorporated herein by reference.

### FIELD

Embodiments described herein relate generally to a semiconductor light emitting element and a manufacturing method thereof.

### BACKGROUND

In a semiconductor light emitting element (for example, light emitting diode), improvement in reliability is desirable.

### DESCRIPTION OF THE DRAWINGS

FIGS. 1A and 1B are schematic cross-sectional views illustrating a semiconductor light emitting element according to a first embodiment.

FIGS. 2A to 2D are schematic cross-sectional views of a process in order illustrating a manufacturing method of the semiconductor light emitting element according to the first embodiment.

FIGS. 3A and 3B are schematic cross-sectional views illustrating the semiconductor light emitting element.

FIG. 4 is a schematic cross-sectional view illustrating the semiconductor light emitting element according to the first embodiment.

FIG. 5 is a schematic cross-sectional view illustrating another semiconductor light emitting element according to the first embodiment.

FIG. 6 is a schematic cross-sectional view illustrating another semiconductor light emitting element according to the first embodiment.

FIG. 7 is a schematic cross-sectional view illustrating another semiconductor light emitting element according to the first embodiment.

FIG. 8 is a schematic cross-sectional view illustrating another semiconductor light emitting element according to the first embodiment.

FIG. 9 is a schematic cross-sectional view illustrating another semiconductor light emitting element according to the first embodiment.

FIG. 10 is a flowchart illustrating a manufacturing method of a semiconductor light emitting element according to a second embodiment.

### DETAILED DESCRIPTION

Embodiments provide a semiconductor light emitting element having high reliability.

In general, according to one embodiment, a semiconductor light emitting element includes: a first layer, a second layer, an intermediate layer, and a third layer. The first layer has a first surface having roughness including a plurality of concave portions with sidewall surfaces that are inclined with respect to a layer plane parallel to a second surface on the first layer opposing the first surface. The first layer includes at least a first conductive-type (first conductivity type) first semiconductor layer. An intermediate layer is adjacent to the second surface. In some embodiments, the intermediate layer is a light-emitting layer, for example, multiple quantum well layer stack or the like. The second layer includes a second conductive-type (second conductivity type) second semiconductor layer and is adjacent to the intermediate layer. The intermediate layer is between the second surface and the second layer. The third layer is provided on the sidewall surfaces of the concave portions. The third layer is a crystalline material having a crystal orientation that corresponds to a crystal orientation of the first layer at the sidewall surfaces. In some embodiments, the third layer may cover only a portion of the sidewall surfaces.

Hereinafter, each embodiment will be described with reference to the accompanying drawings.

Each drawing is schematic and conceptual. Thus, the depicted relationship between the thickness and the width of each part in the drawings and the size ratio between elements in the drawings are not necessarily the same as in an actual device embodying the depicted concepts. In addition, dimensions of or a ratio between parts may be represented differently in different drawings even when the represented parts are the same in an actual device.

In the present disclosure, the same or substantially similar elements may be depicted in more than one drawing. In those cases, the same reference numerals may be used in the different drawings to designate the same or substantially similar elements and description of the previously depicted and described elements may be omitted when appropriate.

### First Embodiment

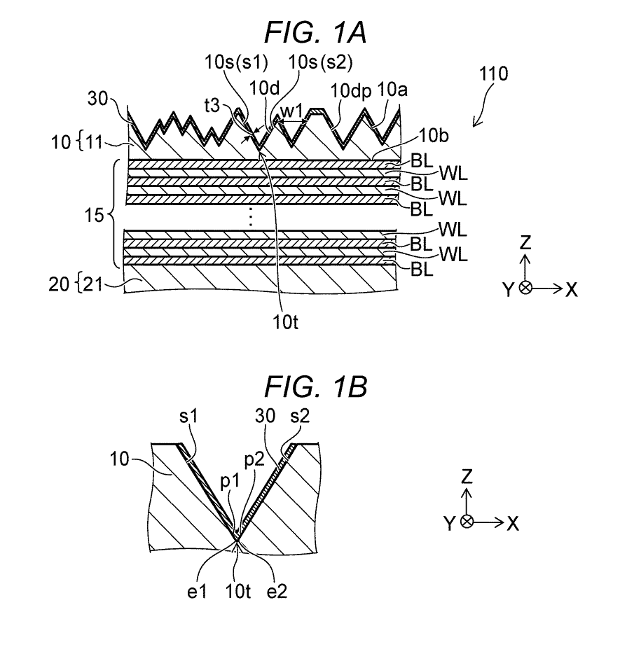

FIGS. 1A and 1B are schematic cross-sectional views illustrating a semiconductor light emitting element according to a first embodiment.

FIG. 1B illustrates an enlarged portion of FIG. 1A. As illustrated in FIG. 1A, a semiconductor light emitting element 110 according to the embodiment includes a first layer 10, a second layer 20, an intermediate layer 15, and a third layer 30.

The first layer 10 has a first surface 10a and a second surface 10b. The first surface 10a has roughness 10dp. The roughness 10dp has a concave portion 10d. A side surface 10s of the concave portion 10d is inclined/angled with respect to surface 10b, for example. The second surface 10b is a surface on the opposite side to the first surface 10a. The first layer 10 includes a first conductive-type first semiconductor layer 11. In the example, an entirety of the first layer 10 is the first semiconductor layer 11; however, as described below, the first layer 10 may instead further include another layer or layers in addition to the first semiconductor layer 11. For this example, the first layer 10 is a first crystal layer.

In the example depicted in FIG. 1a, a bottom (bottom portion 10t) of the concave portion 10d is positioned in the first semiconductor layer 11.

The second layer 20 includes a second conductive-type second semiconductor layer 21. The second layer 20 is separated from the first layer 10 by another layer (e.g., intermediate layer 15). For this example, the second layer 20 is a second crystal layer.

For this example, the first conductive-type is an n-type and the second conductive-type is a p-type. However, in other embodiments, the first conductive-type may instead be p-type and the second conductive-type may be the n-type.

A lamination (layer stacking) direction from the second layer 20 to the first layer 10 is referred to as a Z axis direction. One direction perpendicular to the Z axis direction is referred to as an X axis direction. A direction perpendicular to the Z axis direction and the X axis direction is referred to as a Y axis direction.

The intermediate layer 15 is provided between the second surface 10b and the second layer 20. For example, the intermediate layer 15 is a light emitting layer. Here, the intermediate layer 15 includes a barrier layer BL and a quantum well layer WL. In this example, a plurality of barrier layers BL and a plurality of quantum well layers WL are provided. The plurality of barrier layers BL and the plurality of quantum well layers WL are alternately disposed along the Z axis direction. While a plurality of quantum well layers WL is described, in some embodiments a single quantum well layer WL may be provided rather than a plurality.

A current is supplied to the intermediate layer 15 via the first layer 10 and the second layer 20, and light is emitted from the intermediate layer 15. For example, a peak wavelength of the emitted light is 240 nanometers (nm) or more and 800 nm or less. Strength of the emitted light has the maximum value in the peak wavelength.

The third layer 30 is at least provided in the concave portion 10d of the first surface 10a. In the example, the third layer 30 covers the roughness 10dp in conformance with shapes of the roughness 10dp on the first surface 10a. That is, the third layer is a conformal coating along the first surface 10a. For this example, the third layer 30 is a third crystal layer.

As described above, the side surface 10s of the concave portion 10d is inclined. The side surface 10s is inclined with respect to the Z axis direction, that is, is inclined with respect to an X-Y plane. For example, the concave portion 10d has a pyramidal shape (the sidewalls of each concave portion 10d are planar and meet at a vertex located within bottom portion 10t).

As illustrated in FIG. 1B, the side surface 10s includes a first inclined surface s1 and a second inclined surface s2. The first inclined surface s1 is inclined with respect to the lamination direction (Z axis direction from the second layer 20 to the first layer 10). The second inclined surface s2 is also inclined with respect to the lamination direction and intersects the first inclined surface s1. For example, in the bottom portion 10t of the concave portion 10d, a first end portion e1 of the first inclined surface s1 is connected to a second end portion e2 of the second inclined surface s2.

The third layer 30 comes into contact with the first end portion e1 and the second end portion e2. The third layer 30 includes a first portion p1 coming into contact with the first end portion e1 and a second portion p2 coming into contact with the second end portion e2. The third layer 30 substantially comes into contact with the bottom portion 10t of the concave portion 10d. The first portion p1 and the second portion p2 of the third layer 30 cover a lower portion (the first end portion e1 and the second end portion e2) of the side surface 10s.

For example, a width w1 (distance in a direction perpendicular to the Z axis direction) of the concave portion 10d is in a range of 0.5 times to 10 times the peak wavelength of the light emitted from the intermediate layer 15. For example, if the peak wavelength is 400 nm, the width w1 is 200 nm or more and 4,000 nm or less.

A propagation direction of the light emitted from the intermediate layer 15 is altered and the light is extracted to the outside of the light-emitting element Light extraction efficiency is improved by providing roughness 10dp.

A thickness of the third layer 30 is in a range of about 3 nanometers (nm) or more to about 300 nm or less. For example, the third layer 30 has a thickness (thickness t3) in a direction normal to the first inclined surface s1 that is in a range of 3 nm or more to 300 nm or less. It is preferable that the thickness t3 in a range of 3 nm or more to 30 nm or less.

If the thickness t3 of the third layer 30 is too thin, the quality of the coating provided by the third layer 30 on the roughness 10dp is decreased. For example, pin holes may occur in the third layer 30 and reliability of the light-emitting device may be lowered.

As described above, the third layer 30 extends along a shape of the roughness 10dp of the first surface 10a. If the thickness t3 of the third layer 30 is excessively thick, the shape of the third layer 30 may not be conformal along the shape of the roughness 10dp of the first surface 10a. For example, if it is excessively thick, cracks and the like occur and the intended crystalline nature of the third layer 30 is destroyed. In the thickness t3 of 300 nm or less, the cracks and the like are suppressed.

Light absorption occurs in the third layer 30; however, it is possible to reduce the light absorption to a negligible or inconsequential amount by making the thickness t3 be 50 nm or less. In this context, it is further preferable that the thickness t3 be 30 nm or less.

In this example, nitride semiconductor material is used for the first layer 10, the second layer 20, and the intermediate layer 15. Nitride semiconductor material may be also used for the third layer 30. For example, aluminum nitride (AlN) can be used for the third layer 30.

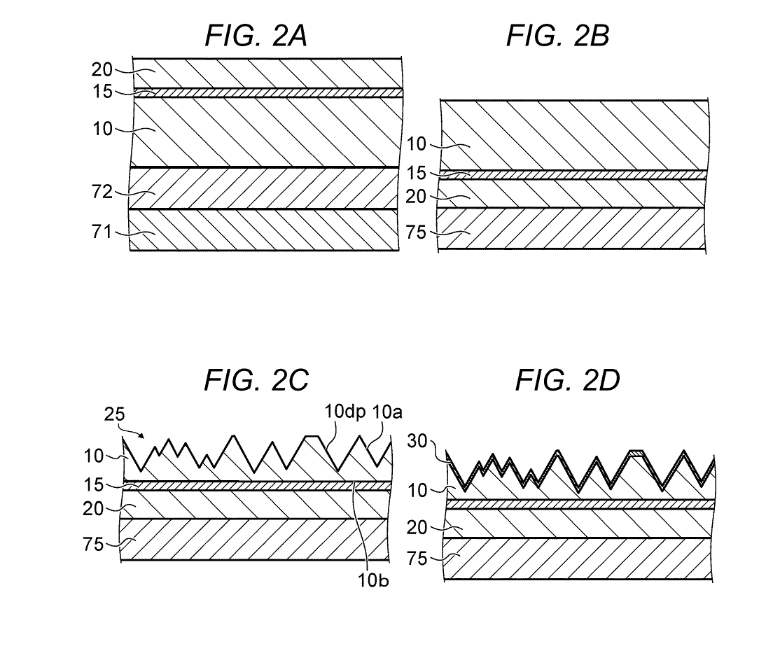

FIGS. 2A to 2D are schematic cross-sectional views of a process illustrating a manufacturing method of the semiconductor light emitting element according to the first embodiment.

As illustrated in FIG. 2A, a buffer layer 72 is formed on a substrate 71. For example, one of Si, SiO₂, quartz, sapphire, GaN, Sic, and GaAs is used for the substrate 71. A crystal plane orientation of the substrate 71 is optional. If Si is used for the substrate 71, for example, at least one of an AlN layer, an AlGaNI layer, and a GaN layer, or a laminated structure thereof is used for the buffer layer 72.

The first layer 10 is formed on the buffer layer 72. For example, after an undoped GaN layer is formed on the buffer layer 72, an n-type first semiconductor layer 11 is formed thereon. The GaN layer containing n-type impurities is used for the first semiconductor layer 11. At least one of Si, Ge, Te, and Sn is used for the n-type impurities. For example, the first semiconductor layer 11 includes an n-side contact layer (not specifically depicted).

The intermediate layer 15 is formed on the first layer 10. For example, an Inₓ₂Ga₁₋ₓ₂N (0<x2<1) layer is used for the quantum well layer WL and a GaN layer is used for the barrier layer BL. Band gap energy of the barrier layer BL is greater than band gap energy of the quantum well layer WL.

The second layer 20 is formed on the intermediate layer 15. For example, as the second layer 20, a GaN layer containing p-type impurities is formed. At least one of Mg, Zn, and C is used for the p-type impurities. For example, the second layer 20 includes a p-side contact layer (not specifically depicted).

As illustrated in FIG. 2B, after a support unit 75 is laminated or joined to the second layer 20, the substrate 71 is removed. At this time, at least a part of the buffer layer 72 may be removed. A part of the buffer layer 72 may also optionally remain. If the buffer layer 72 is left, the remaining buffer layer 72 can be regarded as a part of the first layer 10.

As illustrated in FIG. 2C, the roughness 10dp are formed on a surface of the first layer 10. For example, at least one of wet etching and dry etching is used for the formation of roughness 10dp.

A laminated body 25 is thusly formed. The laminated body 25 here includes the first layer 10, the second layer 20, and the intermediate layer 15 described above.

As illustrated in FIG. 2D, the third layer 30 is formed on the roughness 10dp. For example, if an AlN layer is formed as the third layer 30, a target containing Al is used in a sputter coating system and the third layer 30 is formed by sputtering in an atmosphere containing nitrogen. For example, under conditions when an Electron Cyclotron Resonance sputtering apparatus is used, a flow rate of N₂ is 4 sccm to 7 sccm (for example, 5.5 sccm), a flow rate of Ar is 15 sccm to 25 sccm (for example, 20 sccm), a RF power is 400 W to 600 W (for example, 500 W), and bias power is 400 W to 600 W (for example, 500 W), the AlN crystal layer (third layer 30) is thusly formed. These stated conditions may vary depending on differences between different film-forming apparatuses. Heat treatment of the coated layer (s) may be carried out as necessary.

Thus, according to the describe process, the semiconductor light emitting element 110 illustrated in FIG. 1A can be obtained.

In this embodiment, the third layer 30 is provided on at least the bottom portion 10t of the roughness 10dp in which the side surface 10s is inclined. Thus, the reliability is improved.

For example, a high voltage may be applied to the semiconductor light emitting element 110 and the element may be broken due to static electricity. Specifically, if the roughness 10dp is provided in the first layer 10 and the side surface 10s of the concave portion 10d is the inclined surface, a width of the bottom portion 10t of the concave portion 10d is extremely narrowed. That is, the concave portion 10d having a pyramid shape is provided. In such a case, the static electricity (charge) is locally gathered (concentrated) in the narrow bottom portion 10t. A high voltage is consequently applied to the bottom portion 10t. A distance between the first layer 10 and the second layer 20 is additionally locally short at the bottom portion 10t. Thus, the high voltage which is concentrated in the bottom portion 10t by the static electricity may cause a short circuit to occur between the first layer 10 and second layer 20 at the bottom portion 10t. That is, device/element destruction due to electro-static discharge (ESD) is more likely to occur at the bottom portion 10t.

In this embodiment, the third layer 30 is provided in the bottom portion 10t. Since the third layer 30 is crystalline, a protection function is increased in the third layer 30 compared to a case of amorphous material. Thus, it is possible to effectively suppress occurrence of the ESD destruction at the bottom portion 10t.

For example, there is a reference example in which a SiO₂ layer of an amorphous nature or a SiN layer of an amorphous nature is provided to cover the roughness 10dp of the first surface 10a. In such an amorphous layer, a structure in the layer is random and insulation value provided the layer is uneven. Thus, a portion the amorphous layer in which the insulation protection is low may be locally provided (at random). In the portion in which the insulation value is locally low, a current is more likely to flow. That is, the amorphous layer may include a portion in which ESD resistance (insulation value) is locally low. Thus, if the layer is amorphous, the suppress effect of the ESD destruction across the entirety of the light emitting element may not be sufficient.

In contrast, a third layer 30 is provided in the bottom portion 10t, and the third layer 30 is crystalline rather than amorphous. In the crystal material of third layer 30, uniformity of structure is high and uniformity in insulation value of the third layer 30 is consequently also high. Thus, it is possible to avoid having a portion in which the insulation value is locally low. Thus, it is possible to effectively suppress the ESD destruction by using a crystalline third layer 30.

For a crystalline third layer 30, the film is relatively dense as compared to an amorphous material. Thus, electrical protection performance is higher as compared to a case of amorphous material used as coating on the surface 10a. For example, it is possible to cover the surface 10a of the first layer 10 at high density by covering the concave portion 10d with the crystalline third layer 30. High protection performance is thus obtained. It is possible to suppress the ESD destruction that locally occurs and it is also possible to effectively suppress entry of outside impurities into the first layer 10.

Furthermore, when the current flows during operation of the semiconductor light emitting element 110, the current tends to be concentrated at the bottom portion 10t of the concave portion 10d and a temperature therefore may be locally increased at the bottom portion 10t. Then, localized thermal expansion is caused by the local increase of the temperature, and thereby a local stress may be applied within the first layer 10. If the first layer 10 is damaged by the local stress, the current is likely to be further concentrated in the damaged portion. This phenomenon may be repeated several times and a degree of the damage caused with each cycle may increase at an accelerating rate over time.

However, because the third layer 30 is crystalline it will tend to be relatively strong as compared to amorphous material. Thus, even if the local stress is applied to the first layer 10, the relatively strong third layer 30 may help suppress the generation of damage in the first layer 10.

In contrast, in a reference example in which an amorphous layer is provided in the concave portion 10d, because strength of the amorphous layer is low, an effect for suppressing the damage is low.

In contrast, in the embodiment, the damage may hardly occur in the first layer 10 due to third layer 30 of the crystalline material. Thus, it is possible to obtain high reliability.

The roughness 10dp may be formed by wet etching in some embodiments. In this case, a depth of the concave portion 10d is non-uniform due to non-uniformity in etch rates of the crystalline material of the first layer 10. For example, if a crystal defect, such as dislocation, occurs in the first layer 10, an etching speed may be locally increased in that portion in which the crystal defect occurs. As described above, when a distance between a bottom portion 10t and the second layer 20 that is shorter than other film portions the “locally short” portion is a likely location for the ESD destruction to occur. Similarly, heat is likely to be concentrated in the “locally short” portion of the first film 10 when the light-emitting device is energized.

However, when the crystalline third layer 30 is provided in the bottom portion 10t it is possible to effectively suppress the ESD destruction and the limit the reaction to stress generated at the bottom portion 10t in the “locally short” portion of the first film 10.

In some embodiments, the concave portion 10d may be formed by dry etching. In this case, the depth of the concave portion 10d may be relatively uniform. However, if the side surface 10s of the concave portion 10d is inclined, the ESD is likely to occur and the stress is also likely to be concentrated in the bottom portion 10t of the concave portion 10d. Thus, it is possible to suppress the destruction due to the ESD destruction and the stress by providing the crystalline third layer 30.

The crystal orientation of the third layer 30 may extend along the crystal orientation of the first layer 10. For example, in the third layer 30, the crystal orientation of the first portion p1 extends along the crystal orientation in the first end portion e1 of the first inclined surface s1. Then, the crystal orientation of the second portion p2 extends along the crystal orientation in the second end portion e2 of the second inclined surface s2.

The third layer 30 can thus be substantially lattice matched with the first layer 10. However, given different surface orientations at the roughened surface of the first layer, the third layer 30 can be considered pseudo-lattice matched with the first layer 10. That is, the third layer 30 is substantially coherent with the first layer 10 in localized regions. The third layer 30 takes over lattice information of the adjacent first layer 10. The third layer 30 may be subjected to epitaxial growth on the side surface 10s of the first layer 10.

The crystal orientation of the third layer 30 extends along the crystal orientation of the first layer 10 and thereby combination of the third layer 30 and the first layer 10 is strong. For example, the ESD resistance is specifically improved. Even if the stress is applied to the first layer 10, the damage occurred in the first layer 10 may be specifically suppressed by the third layer 30 strongly combined with the first layer 10.

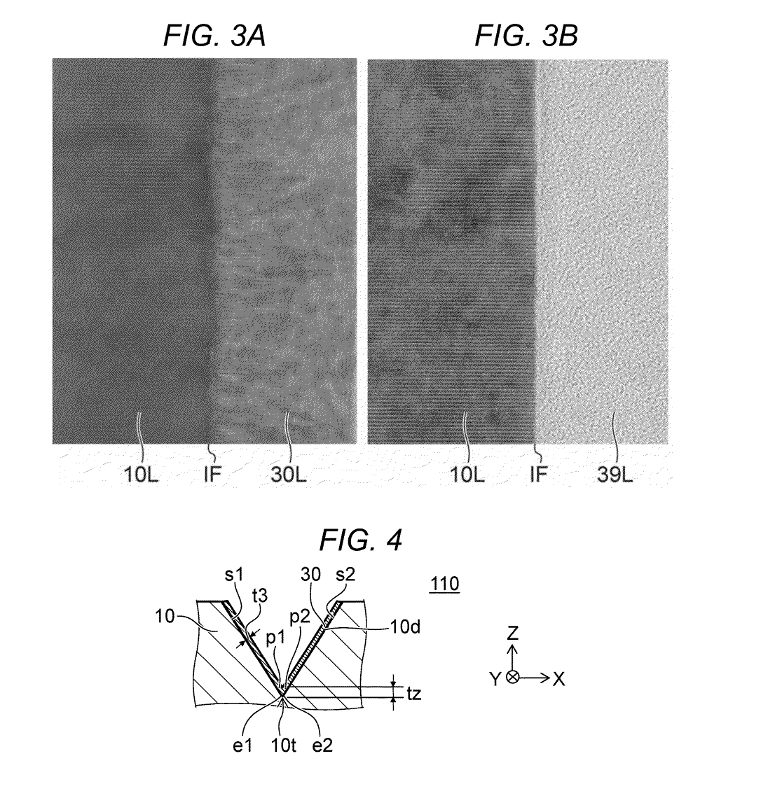

FIGS. 3A and 3B are schematic cross-sectional views illustrating the semiconductor light emitting element. FIG. 3A corresponds to a sample in which an AlN layer 30L corresponding to the third layer 30 is formed on a GaN layer 10L corresponding to the first layer 10. FIG. 3B corresponds to a sample in which an amorphous SiN layer 39L is formed on the GaN layer 10L. In the drawings, a Transmission Electron Microscope (TEM) image is illustrated.

As illustrated in FIG. 3A, regular striped patterns derived from the crystal are observable in the GaN layer 10L. Then, the regular striped patterns derived from the crystal are also observable in the AlN layer 30L. It is therefore known that the crystal in the AlN layer 30L is substantially lattice matched with the GaN layer 10L at an interface IF between the GaN layer 10L and the AlN layer 30L.

As illustrated in FIG. 3B, the striped patterns are not observable in the amorphous SiN layer 39L.

A high device reliability is obtained by using an AlN layer 30L that is lattice matched with a GaN layer 10L.

A first layer 10, for example, may be a nitride semiconductor of a c-surface orientation. Then, if the concave portion 10d is formed by the wet etching, for example, the first inclined surface s1 is likely to be (10 1̅ 3̅) plane, (10 1̅ 1̅) plane, or (10 1̅ 2̅) plane. The plane orientation of the inclined surface is finely varied or may be controlled by adjusting etching conditions. The angle may be increased or decreased in the vertical direction. For example, if the second inclined surface s2 is formed by the wet etching, the second inclined surface s2 is also likely to be (10 1̅ 3̅) plane, (10 1̅ 1̅) plane, or (10 1̅ 2̅) plane. For example, when the first inclined surface s1 is (10 1̅ 1̅) plane, the second inclined surface s2 is likely to be (101 1̅) plane. For example, when the first inclined surface s1 is (10 1̅ 3̅) plane, the second inclined surface s2 is likely to be (101 3̅) plane. For example, when the first inclined surface s1 is (110 1̅) plane, the second inclined surface s2 is likely to be (1 1̅ 1̅) plane. However, the possible embodiments are not limited to those plane orientations. Note that over-lined numbers in these notations correspond to negative index values. Even if the concave portion 10d is formed by the wet etching, the angle between the first inclined surface s1 and the second inclined surface s2 may be an angle other than the above description by setting processing conditions.

Even if the concave portion 10d is formed by the dry etching, the angle between the first inclined surface s1 and the second inclined surface s2 may be set to be a desired angle. The angle may be controlled by setting the processing conditions.

For example, the angle between the first inclined surface s1 and the second inclined surface s2 is in a range of 60 degrees or more to 120 degrees or less. High light extraction efficiency is obtained in this angle range. It is preferable that the angle be approximately 80 degrees (for example, 70 degrees or more and 90 degrees or less). In this case, the light extraction efficiency may be increased.

For example, a first nitride semiconductor (for example, an n-type GaN or the like) is used for the first layer 10. A second nitride semiconductor (for example, a p-type GaN and the like) is used for the second layer 20. If the nitride semiconductor is used, the concave portion 10d has a hexagonal pyramid shape.

In this example, aluminum nitride (AlN) is used for the third layer 30. If the nitride semiconductor is used for the first layer 10 and AlN is used as the third layer 30, the lattice between the first layer 10 and the third layer 30 is likely to be well matched. Since AlN has high coatability (good film forming characteristics), a third layer 30 that is uniform along the shape of the roughness 10dp is obtained.

AlN used for the third layer 30 may contain a small amount of impurities (for example, oxygen and the like). For example, aluminum oxynitride (AlON) may be used for the third layer 30. If oxygen concentration is low, preferable crystalline material is obtained. It is preferable that impurity concentration, such as oxygen, be 20% or less. Thus, it is possible to maintain good crystalline structure.

In the embodiment, when nitride semiconductor material is used for the first layer 10, at least one of silicon carbide (SiC) and zinc oxide (ZnO) may be used for the third layer 30. Lattice constants of those materials are relatively close to a lattice constant of GaN. Thus, good crystalline structure is obtained in the third layer 30. Al₂O₃ may also be used for the third layer 30.

In an example embodiment, a distance between the bottom portion 10t of the concave portion 10d and the second layer 20 in the Z axis direction is in a range of about 300 nm or more to about 5,000 nm or less. This distance approximately corresponds to a thickness of the first layer 10. For example, if this distance is excessively short, spread of current in the first layer 10 may be insufficient, light emission thus becomes non-uniform, and the light emission efficiency is decreased. Furthermore, if the distance is excessively short, an occurrence rate of the ESD destruction is increased. If the distance is excessively long, light absorption by layer 10 is increased and efficiency is reduced in the first layer 10.

FIG. 4 is a schematic cross-sectional view illustrating the semiconductor light emitting element according to the first embodiment. As illustrated in FIG. 4, the third layer 30 includes the first portion p1. The first portion p1 is a portion coming into contact with the first end portion e1 of the first inclined surface s1. A thickness tz of the first portion p1 in the Z axis direction is between one or more and three or less times the thickness (thickness t3) in the direction normal to the first inclined surface s1 of the first portion p1. That is, the third layer 30 is provided having a substantially uniform thickness along the shape of the concave portion 10d. That is, the surface of the concave portion 10d is covered by the substantially uniform third layer 30.

For example, one crystal layer is formed from the first inclined surface s1, another crystal layer is formed from the second inclined surface s2, and those crystal layers may be combined or joined. A position in which those crystal layers are combined is on the bottom portion 10t of the concave portion 10d. At this time, a case where crystal layer is grown only on the first inclined surface s1 and the second inclined surface s2, and the crystal layer is not grown on the bottom portion 10t is a case where cavities are grown on the bottom portion 10t. In such a case, suppressive effect of the EAD destruction and stress destruction may not be sufficiently increased on the bottom portion 10t.

Thus, it is preferable that cavities are not formed on or above the bottom portion 10t. That is, the third layer 30 is formed so as to come into contact with the bottom portion 10t of the concave portion 10d.

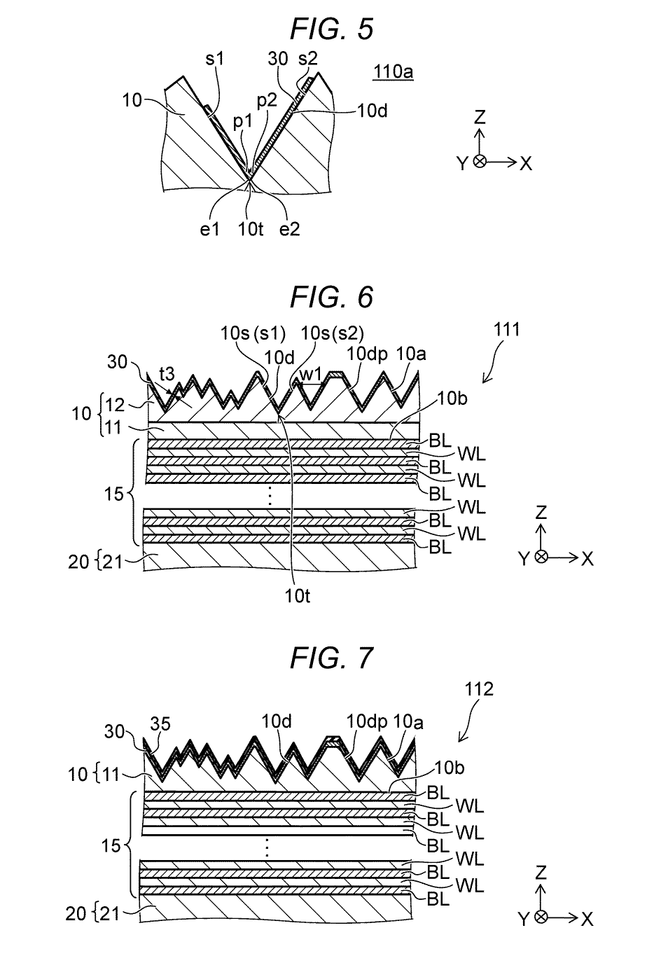

FIG. 5 is a schematic cross-sectional view illustrating another semiconductor light emitting element according to the first embodiment.

As illustrated in FIG. 5, in another semiconductor light emitting element 110a according to the embodiment, a third layer 30 is not provided on all portions of the upper surface of first layer 10. The bottom (bottom portion 10t) of a concave portion 10d is covered by third layer 30, but other portions of first layer 10 are not covered by third layer 30. That is, as described above, ESD destruction and the like is primarily likely to occur at a bottom portion 10t. Thus, the third layer 30 may be provided in the bottom portion 10t and not on other portions. Thus, it is possible to increase reliability without fully covering first layer 10 with third layer 30.

It is sufficient that the third layer 30 is provided in the concave portion 10d, and it is not necessary to provide the third layer 30 on the convex portions of a roughness 10dp.

FIG. 6 is a schematic cross-sectional view illustrating another semiconductor light emitting element according to the first embodiment. As illustrated in FIG. 6, in a semiconductor light emitting element 111, a first layer 10 includes a low impurity concentration layer 12. A first semiconductor layer 11 is disposed between the low impurity concentration layer 12 and intermediate layer 15.

An impurity concentration of a first conductive-type impurity (and/or dopant) in the first semiconductor layer 11 is higher than an impurity concentration in the low impurity concentration layer 12. For example, an n-type GaN is used for the first semiconductor layer 11 and an i-GaN in which the impurity is not doped is used for the low impurity concentration layer 12.

In the example, a bottom (bottom portion 10t) of the concave portion 10d is positioned in the low impurity concentration layer 12. In the low impurity concentration layer 12, the electrical conductivity is lower than that of the first semiconductor layer 11. It is possible to suppress concentration of the current at the bottom portion 10t and to improve reliability by positioning the bottom portion 10t in the low impurity concentration layer 12.

In the semiconductor light emitting element 111, a part of the low impurity concentration layer 12 is removed so the first semiconductor layer 11 and an electrode can be electrically connected without connecting through the low impurity concentration layer 12.

FIG. 7 is a schematic cross-sectional view illustrating another semiconductor light emitting element. As illustrated in FIG. 7, in semiconductor light emitting element 112, an insulation film 35 is provided on the third layer 30. For example, at least one of silicon oxide, silicon nitride, and silicon oxynitride is used for the insulation film 35. These films are amorphous. A thickness of the insulation film 35 is, for example, within a range of about 10 nm or more and about 500 nm or less. Reliability may be further increased by providing the insulation film 35. Inclusion of insulation film 35 is optional and may be omitted.

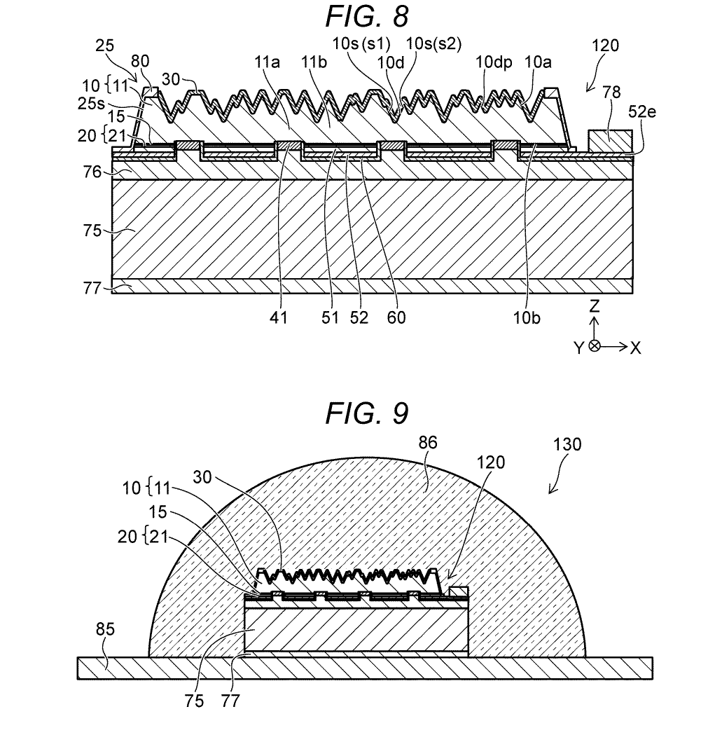

FIG. 8 is a schematic cross-sectional view illustrating another semiconductor light emitting element. As illustrated in FIG. 8, in semiconductor light emitting element 120, a first electrode 41, a second electrode 51, a wiring layer 52, an insulation layer 60, a passivation film 80, a support unit 75, a bonding layer 76, a back electrode 77, a pad electrode 78 are provided.

The first semiconductor layer 11 includes a first semiconductor region 11a and a second semiconductor region 11b. A direction from the second semiconductor region 11b to the first semiconductor region 11a intersects the Z axis direction. That is, a conceptual line extending from the first semiconductor region 11a to the second semiconductor region 11b crosses the z axis direction. As an example, the first semiconductor region 11a and the second semiconductor region 11b may be adjacent to each other or spaced from each other along the x axis direction.

An intermediate layer 15 is provided between the second semiconductor region 11b and a second layer 20 (second semiconductor layer 21).

The second layer 20 and the intermediate layer 15 are disposed between the first layer 10 and the support unit 75.

The first electrode 41 is disposed between the first semiconductor region 11b and the support unit 75. The first electrode 41 is electrically connected to the first semiconductor layer 11. The bonding layer 76 is disposed between the first electrode 41 and the support unit 75. In the example, the support unit 75 is conductive. The bonding layer 76 is conductive and, the support unit 75 and the first electrode 41 are thus electrically connected.

In the example, the back (back-side) electrode 77 is provided and the support unit 75 is disposed between the back electrode 77 and the bonding layer 76.

The second electrode 51 is provided between the support unit 75 and the second semiconductor layer 21. The wiring layer 52 is provided between the support unit 75 and the second electrode 51. The wiring layer 52 is electrically connected to the second semiconductor layer 21 through the second electrode 51. For example, the wiring layer 52 extends in directions parallel to the X-Y plane.

The insulation layer 60 is disposed between the support unit 75 and the wiring layer 52. The bonding layer 76 is provided between the support unit 75 and the insulation layer 60. The bonding layer 76 electrically connected to the support unit 75 is electrically insulated from the wiring layer 52, the second electrode 51, and the second semiconductor layer 21 by the insulation layer 60.

One end 52e of the wiring layer 52 extends to a position between the pad electrode 78 and the support unit 75. The wiring layer 52 is electrically connected to the pad electrode 78.

The passivation film 80 is provided on a side surface 25s of a laminated body 25 that includes the first layer 10, the intermediate layer 15, and the second layer 20. Thus, the laminated body 25 is protected.

A voltage is applied between the pad electrode 78 and the back electrode 77. A current is supplied to the intermediate layer 15 through the wiring layer 52, the second electrode 51, the second semiconductor layer 21, the support unit 75, the bonding layer 76, the first electrode 41, and the first semiconductor layer 11. For example, the semiconductor light emitting element 120 is an LED.

The light emitted from the intermediate layer 15 is reflected on the first electrode 41 and the second electrode 51, passes through the third layer 30, and is emitted to the outside.

At least one of silver, silver alloy, and aluminum (Al) is used for the first electrode 41 and the second electrode 51. High light reflectance is obtained. The electrodes may contain at least one of Ni, Pt, and Ti. For example, good ohmic contact with the semiconductor layer is obtained.

For example, aluminum (Al), copper (Cu), and the like are used for the wiring layer 52. For example, at least one of silicon oxide, silicon nitride, and silicon oxynitride is used for the insulation layer 60 and the passivation film 80.

High reliability is obtained by using the third layer 30 in the semiconductor light emitting element 120.

In the semiconductor light emitting element 120, a refractive index of GaN used for the first layer 10 is approximately 2.4. For example, a refractive index of AlN used for the third layer 30 is approximately 2.1. The refractive index is decreased in order of the first layer 10, the third layer 30, and the outside (air). As a result, high light extraction efficiency is obtained.

FIG. 9 is a schematic cross-sectional view illustrating another semiconductor light emitting element according to the first embodiment. As illustrated in FIG. 9, in another semiconductor light emitting element 130 according to the embodiment, a mounting member 85 and a wavelength conversion layer 86 are further provided in the semiconductor light emitting element 120.

A back electrode 77 is disposed between the mounting member 85 and a support unit 75. A third layer 30 is disposed between the wavelength conversion layer 86 and a first layer 10.

For example, the light emitted from an intermediate layer 15 passes through the third layer 30, and is incident on the wavelength conversion layer 86. Some of light having a first wavelength emitted from the intermediate layer 15 is absorbed by the wavelength conversion layer 86 and is converted into light having a second wavelength different from the first wavelength. For example, a phosphor layer is used for the wavelength conversion layer 86. For example, in the phosphor layer in which the light of the first wavelength is blue, the blue light is converted into at least one of yellow and red light. For example, the light after passing through the wavelength conversion layer 86 is emitted as a substantially white light.

In the semiconductor light emitting element 130, high reliability is obtained.

In the semiconductor light emitting element 130, for example, the refractive index of the wavelength conversion layer 86 is approximately 1.6. Thus, the refractive index is decreased in order of the first layer 10, the third layer 30, the wavelength conversion layer 86, and the outside (air). As a result, high light extraction efficiency is obtained. For example, it is possible to improve the light extraction efficiency compared to a case where SiO₂ film and the like are used in place of the third layer 30.

For example, In a Thin-Film type semiconductor light emitting element, in order to improve the light extraction efficiency, roughness is provided on the surface of the crystal layer. In the concave portion of the roughness, a current locally concentrates. Minute current leakage occurs at these concave portions. Furthermore, the ESD resistance of the device is low and long term reliability may be insufficient. In an embodiment, minute current leakage is decreased by providing a crystal layer (e.g., third layer 30) in the concave portion. Then, the ESD resistance is improved and the long term reliability is improved.

### Second Embodiment

The second embodiment relates to a manufacturing method of a semiconductor light emitting element.

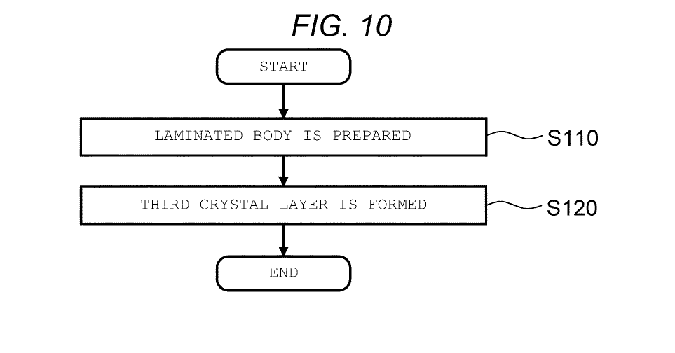

FIG. 10 is a flowchart illustrating the manufacturing method of the semiconductor light emitting element according to a second embodiment.

As illustrated in FIG. 10, a laminated body (such as laminated body 25) is prepared (step S110). The laminated body 25 includes a first layer 10, a second layer 20, and an intermediate layer 15. The first layer 10 has a first surface 10a having roughness 10dp including a concave portion 10d in which a side surface 10s is inclined and a second surface 10b opposite to the first surface 10a. The first layer 10 includes a first conductive-type first semiconductor layer 11. The second layer 20 includes a second conductive-type second semiconductor layer 21. The intermediate layer 15 is provided between the second surface 10b and the second layer 20. That is, for example, the process described in FIGS. 2A to 2C is performed.

Then, the third crystal layer (e.g., third film 30) is formed on the concave portion 10d of the first surface 10a (step S120). For example, the process illustrated in FIG. 2D is performed.

Thus, the semiconductor light emitting element according to the described embodiments may be obtained.

In the manufacturing method, the crystal orientation of the third layer 30 extends along the crystal orientation of the first layer 10.

For example, in formation of the third layer 30, the third layer 30 is formed by sputtering in an atmosphere containing nitrogen using a sputter target containing aluminum. Thus, it is possible to stably form the third layer 30 of which the crystal orientation extends along the crystal orientation of the first layer 10.

In the second embodiment, it is possible to manufacture the semiconductor light emitting element having high reliably with high productivity.

In the semiconductor light emitting element and the manufacturing method of the semiconductor light emitting element according to the embodiment, for example, a Metal-Organic Chemical Vapor Deposition (MOCVD) method, a Metal-Organic Vapor Phase Epitaxy (MOVPE), a Molecular Beam Epitaxy (MBE) method, a Halide Vapor Phase Epitaxy (HVPE) method, and the like may be used for a growing method of crystal layers (such as, in some embodiments, first layer 10 and third layer 30).

When the MOCVD method or the MOVPE method is used, the following raw materials (precursors) may be used when forming each crystal layer. For example, it is possible to use trimethyl gallium (TMGa) and triethyl gallium (TEGa) for the raw material of Ga. For example, it is possible to use trimethyl indium (TMIn) and triethyl indium (TEIn) for the raw material of In. It is possible to use trimethyl aluminum (TMAl) and the like for the raw material of Al. For example, it is possible to use ammonia (NH₃), monomethyl hydrazine (MMHy), dimethyl hydrazine (DMHy), and the like for the raw material for incorporation of nitrogen (N). For example, it is possible to use monosilane (SiH₄), disilane (Si₂H₆), and the like for the raw material for incorporation of silicon (Si).

In this disclosure, “nitride semiconductor” includes semiconductors having a chemical formula of BₓIn_{y}Al_{z}Ga_{1-x-y-z}N (0≦x≦1, 0≦y≦1, 0≦z≦1, and x+y+z≦1), where “B” designates boron, “In” designates indium, “Al” designates aluminum, “Ga” designates gallium, and “N” designates nitrogen. Furthermore, the “nitride semiconductor” may further include one V group elements other than nitrogen (N), various elements added for controlling various physical properties such as a conductivity type, and o various elements unintentionally present as impurities, for example, elements present at trace levels and/or levels at which it is technically and/or economically infeasible to reduce.

Moreover, in this disclosure, “normal to” “orthogonal,” “perpendicular,” and “parallel” are not intended to strictly require precisely 90° intersections or mathematically precise parallelism but also encompasses variation in values within reasonable manufacturing variations and tolerances, and should be treated as meaning “substantially normal to” substantial orthogonal,” “substantial perpendicular,” and “substantially parallel,” respectively.

Hereto, embodiments have been described with reference to specific examples. However, the present disclosure is not limited to the specific examples. For example, various possible configurations of each element such as the crystal layer, the semiconductor layer, the intermediate layer, the electrode, and the support unit contained in the semiconductor light emitting element are included in the disclosed embodiments as long as those skilled in the art may carry out the embodiments in the same manner and may obtain the same effects by appropriately selecting the specific configurations from known ranges.

A combination of any two or more elements from specific examples is, to the extent of technical feasibility, included within in the scope of the disclosed embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor light emitting element, comprising:
a first layer including at least a first semiconductor layer of a first conductivity-type, the first layer having a first surface that has roughness that includes a plurality of concave portions with sidewall surfaces that are inclined with respect to a layer plane that is parallel to a second surface of the first layer, the first and second surfaces being on opposing sides of the first layer;
an intermediate layer adjacent to the second surface;
a second layer including a second semiconductor layer of a second conductivity type and adjacent to the intermediate layer, the intermediate layer being between the second surface and the second layer; and
a third layer on the sidewall surfaces of the concave portions, the third layer being a crystalline material having a crystal orientation that corresponds to a crystal orientation of the first layer at the sidewall surfaces, wherein a material of the first layer is different from the crystalline material.

2. The semiconductor light emitting element according to claim 1, wherein a thickness of the third layer is greater than or equal to 3 nanometers and less than or equal to 300 nanometers.

3. The semiconductor light emitting element according to claim 2, wherein a concave portion in the plurality of concave portions has a pyramidal shape.

4. The semiconductor light emitting element according to claim 1, wherein a concave portion in the plurality of concave portions has a pyramidal shape.

5. The semiconductor light emitting element according to claim 4, wherein
the sidewall surfaces include:
a first inclined surface and a second inclined surface intersecting the first inclined surface,
a bottom portion of the concave portion is at an intersection of the first and second inclined sidewalls, and a first end portion of the first inclined surface is connected to a second end portion of the second inclined surface at the intersection, and
the third layer is contacting the first end portion and the second end portion.

6. The semiconductor light emitting element according to claim 5, wherein the third layer contacts the bottom portion.

7. The semiconductor light emitting element according to claim 5, wherein
the third layer includes a first portion contacting the first end portion and a second portion contacting the second end portion,
a crystal orientation of the first portion corresponds to a crystal orientation of the first end portion, and
a crystal orientation of the second portion corresponds to a crystal orientation of the second end portion.

8. The semiconductor light emitting element according to claim 5, wherein the third layer has a thickness in a direction normal to the first inclined surface that is greater than or equal to 3 nanometers and less than or equal to 30 nanometers.

9. The semiconductor light emitting element according to claim 5, wherein
the third layer includes a first portion coming into contact with the first end portion, and
a thickness of the first portion along a direction orthogonal to the layer plane is in a range of one to three times a thickness of the first portion along a direction normal to the first inclined surface.

10. The semiconductor light emitting element according to claim 1, wherein
the sidewall surfaces include a first inclined surface and a second inclined surface intersecting the first inclined surface,
a bottom portion of the concave portion is at an intersection of the first and second inclined sidewalls, a first end portion of the first inclined surface is connected to a second end portion of the second inclined surface at the intersection, and
the third layer is contacting the first end portion and the second end portion.

11. The semiconductor light emitting element according to claim 10, wherein
the third layer includes a first portion contacting the first end portion and a second portion contacting the second end portion,
a crystal orientation of the first portion corresponds to a crystal orientation of the first end portion, and
a crystal orientation of the second portion corresponds to a crystal orientation of the second end portion.

12. The semiconductor light emitting element according to claim 11, wherein the third layer contacts the bottom portion.

13. The semiconductor light emitting element according claim 1, wherein
the first semiconductor layer is gallium aluminum nitride, and
the third layer is aluminum nitride.

14. The semiconductor light emitting element according to claim 1, wherein the first layer includes a third semiconductor layer having an impurity concentration that is less than an impurity concentration of the first semiconductor layer, the first semiconductor layer being between the third semiconductor layer and the first surface.

15. The semiconductor light emitting element according to claim 1, further comprising:
an insulation film on the third layer, the third layer being between the insulation layer and the first layer.

16. A light emitting element, comprising:
a laminated body extending in a layer plane and having a first side and a second side opposing the first side, the laminated body including:
a first layer at a first surface on the first side and including a first nitride semiconductor material of a first conductivity type, the first surface having a roughness that includes a plurality of concave portions with sidewall surfaces angled with respect to the layer plane,
a light-emitting layer adjacent to the first layer in a first direction orthogonal to the layer plane, and
a second layer on the second side and adjacent to the light-emitting layer in the first direction, the light-emitting layer being between the first and second layer in the first direction, the second layer including a second nitride semiconductor material of a second conductivity type; and
a third layer comprising crystalline material disposed on the first surface, a material of the first layer being different form the crystalline material, the third layer contacting at least portions of the sidewall surfaces, the third layer having a local crystal plane orientation that matches a crystal plane orientation of a portion of the first layer that is present at the sidewall surfaces.

17. The light emitting element of claim 16, wherein the third layer is aluminum nitride.

18. The light emitting element of claim 16, wherein the third layer completely covers the first surface as a conformal film.

19. A manufacturing method, comprising:
forming a first layer including at least a first semiconductor layer of a first conductivity-type, the first layer having a first surface that has roughness that includes a plurality of concave portions with sidewall surfaces that are inclined with respect to a layer plane that is parallel to a second surface of the first layer, the first and second surfaces being on opposing sides of the first layer,
forming an intermediate layer adjacent to the second surface;
forming a second layer including a second semiconductor layer of a second conductivity type adjacent to the intermediate layer, the intermediate layer being disposed between the second surface and the second layer; and
forming a third layer on the sidewall surfaces of the concave portions, the third layer being a crystalline material having a crystal orientation that corresponds to a crystal orientation of the first layer at the sidewall surfaces, wherein a material of the first layer is different from the crystalline material.

20. (canceled)

21. The manufacturing method of claim 19, wherein the third layer is an aluminum nitride film and is formed conformally on the first surface.
